(19) United States
(12) Patent Application Publication
(10) Pub. No.: US 2014/0323028 A1
(43) Pub. Date: Oct. 30, 2014

(54) CHASSIS OF ELECTRONIC DEVICE

(71) Applicant: HON HAI PRECISION INDUSTRY CO., LTD., New Taipei (TW)

(72) Inventors: TAI-WEI LIN, New Taipei (TW); SHIH-CHIEH CHEN, New Taipei (TW)

(73) Assignee: HON HAI PRECISION INDUSTRY CO., LTD., New Taipei (TW)

(21) Appl. No.: 14/014,416

(22) Filed: Aug. 30, 2013

(30) Foreign Application Priority Data
Apr. 30, 2013 (TW) 102115403

(51) Int. Cl. H05K 7/20

(52) U.S. Cl. CPC H05K 7/20145
USPC 454/184

(57) ABSTRACT

A chassis includes a bottom plate, a number of fans mounted to the bottom plate, an air guiding member mounted to the bottom plate and near the fans, and a number of data storage devices received in the air guiding member. The air guiding member includes a top plate and a partition plate below the top plate. The partition plate is near the fans. The partition plate divides the air guiding member into a first aisle below the partition plate and a second aisle above the partition plate. The top plate and the partition plate bound an opening. The data storage devices are located below the partition plate. A part of airflow from the fans flows into the first aisle; another part of airflow from the fans flows through the second aisle and the opening, and flows toward the data storage devices away from the fans.

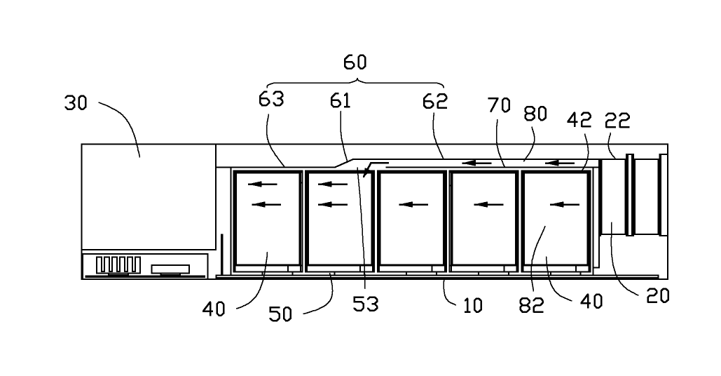

### BACKGROUND

1. Technical Field

The present disclosure relates to a chassis of an electronic device.

2. Description of Related Art

A number of hard disk drives (HDDs) are generally mounted in a chassis of a server. And conventionally, a number of fans are configured to dissipate heat generated by the HDDs. After the airflow generated by the fans flows through the HDDs near the fans, the temperature of the airflow increases. Accordingly, the effect of heat dissipation of the HDDs farther away from the fans is not ideal.

### BRIEF DESCRIPTION OF THE DRAWING

Many aspects of the present embodiments can be better understood with reference to the following drawing. The components in the drawing are not necessarily drawn to scale, the emphasis instead being placed upon clearly illustrating the principles of the present embodiments. Moreover, in the drawing, the view is schematic, and like reference numerals designate corresponding parts throughout the view.

The FIGURE is a schematic view of an embodiment of a chassis.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

The FIGURE shows an exemplary embodiment of a chassis of an electronic device. The chassis includes a bottom plate 10, a plurality of fans 20 mounted to the bottom plate 10, a power supply unit 30 mounted to the bottom plate 10, an air guiding member 50 located between the fans 20 and the power supply unit 30, and a plurality of data storage devices 40 received in the air guiding member 50. The air guiding member 50 is supported on the bottom plate 10.

The air guiding member 50 includes a top plate 60 and a partition plate 70. The top plate 60 includes a first plate 62 parallel to the bottom plate 10 and near the fans 20, a second plate 63 parallel to the first plate 62 and away from the fans 20, and a slanting guiding plate 61 connected between the first plate 62 and the second plate 63. The second plate 63 is located below the first plate 62. The height of the first plate 62 is the same as the height of top walls 22 of the fans 20. The partition plate 70 is parallel to and below the first plate 62. The partition plate 70 is near the fans 20. The height of the partition plate 70 is the same as the height of the second plate 63. The second plate 63 and the partition plate 70 bound an opening 53. The partition plate 70 divides the air guiding member 50 into a first aisle 82 below the partition plate 70 and a second aisle 80 above the partition plate 70. The data storage devices 40 are located below the partition plate 70.

A part of airflow from the fans 20 flows into the first aisle 82, flows through the data storage devices 40 near the fans 20, and then flows through the data storage devices 40 away from the fans 20. Another part of airflow from the fans 20 flows into the second aisle 80, flows through the opening 53, and then flows toward the data storage devices 40 away from the fans 20. Therefore, the data storage devices 40 away from the fans 20 can also obtain enough airflow, and the heat dissipation of the data storage devices 40 is substantially even.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A chassis, comprising:
a bottom plate;
a plurality of fans mounted to the bottom plate; and
an air guiding member mounted to the bottom plate and near the fans, the air guiding member comprising a top plate and a partition plate below the top plate, the partition plate being adjacent to the fans, the partition plate dividing the air guiding member into a first aisle below the partition plate and a second aisle above the partition plate, the top plate and the partition plate bounding an opening;
wherein when a plurality of data storage devices is installed in the air guiding member and located below the partition plate, a part of airflow from the plurality of fans flows into the first aisle, another part of airflow from the plurality of fans flows through the second aisle and the opening, and flows toward the data storage devices away from the plurality of fans.

2. The chassis of claim 1, wherein the top plate comprises a first plate parallel to the bottom plate and near the plurality of fans, a second plate below the first plate and away from the plurality of fans, and a slanting guiding plate connected between the first plate and the second plate, the opening is bounded between the partition plate and the second plate.

3. The chassis of claim 2, wherein a height of the first plate is the same as a height of top walls of the plurality of fans.

4. The chassis of claim 2, wherein the second plate is parallel to the first plate.

5. The chassis of claim 2, wherein a height of the second plate is the same as a height of the partition plate.
